(19) United States
(12) Patent Application Publication
(10) Pub. No.: US 2024/0395779 A1
(43) Pub. Date: Nov. 28, 2024

(54) OPTOELECTRONIC SOLID STATE ARRAY

(71) Applicant: VueReal Inc., Waterloo (CA)

(72) Inventors: Gholamreza CHAJI, Waterloo (CA); Mae GAO, Kitchener (CA); Ehsanollah FATHI, Waterloo (CA); Pranav GAVIMENI, Kitchener (CA)

(73) Assignee: VueReal Inc., Waterloo, ON (CA)

(21) Appl. No.: 18/796,591

(22) Filed: Aug. 7, 2024

Related U.S. Application Data
(63) Continuation of application No. 17/432,585, filed on Aug. 20, 2021.
(60) Provisional application No. 62/962,027, filed on Jan. 16, 2020.
(60) Provisional application No. 62/947,950, filed on Dec. 13, 2019.
(60) Provisional application No. 62/913,790, filed on Oct. 11, 2019.
(60) Provisional application No. 62/808,589, filed on Feb. 21, 2019.

(51) Int. Cl. H01L 25/075; H01L 33/62

(52) U.S. Cl. CPC H01L 25/0753; H01L 33/62; H01L 2224/10126; H01L 2224/73204; H01L 2933/0066

(57) ABSTRACT

Structures and methods are disclosed for fabricating optoelectronic solid state array devices. In one case a backplane and array of micro devices is aligned and connected through bumps.

### BACKGROUND AND FIELD OF THE INVENTION

The present disclosure relates to optoelectronic solid state array devices and more particularly relates to bonding a micro device array to a backplane using a reliable approach.

### SUMMARY

The present invention relates to a method to fabricate a microdevice array. The method comprises providing a substrate having one or more micro devices with a bump at a top surface of the micro devices, providing a backplane comprising one or more bumps corresponding to the bumps on the micro devices, planarizing spaces between the micro devices and the bumps with at least one planarization layer, patterning the at least one planarization layer to clear the bumps, aligning and bringing the micro devices and the backplane in contact, and curing the at least one planarization layer.

According to another embodiment, a microdisplay comprises of a substrate having one or more micro devices having bumps on a top surface of the one or more micro devices, a backplane comprising one or more bumps corresponding to the bumps on the one or more micro devices, at least one patterned planarization layer that covers spaces between the micro devices and the bumps, wherein the substrate and the backplane are aligned and connected through curing the at least one patterned planarization layer.

According to yet another embodiment, a method of fabricating a micro device array may comprise steps of providing an array of micro devices having bumps on a top surface of a substrate, forming at least one common contact at one or more common layers of the substrate, forming a bridge for the common contact close to a height of the micro devices; forming an electrode to bring the common contact to the top of the bridge, forming at least one common bump on top of the electrode, providing a backplane comprising one or more bumps corresponding to the common bumps and the bumps on the micro devices, aligning and bringing the microdevices and the backplane in contact, and bonding the micro devices and the backplane through bumps.

### BRIEF DESCRIPTION OF THE DRAWINGS

The foregoing and other advantages of the disclosure will become apparent upon reading the following detailed description and upon reference to the drawings.

FIG. 1A shows a flow chart illustrating a method, according to one embodiment of the present invention.

FIG. 1B shows another flow chart illustrating a method, according to one embodiment of the present invention.

FIG. 2A shows a cross-sectional view of a micro device array on a micro device substrate, according to one embodiment of the present invention.

FIG. 2B shows a cross-sectional view of the micro device array of FIG. 2A after patterning an adhesive layer, according to one embodiment of the present invention.

FIG. 2C shows a cross-sectional view of a micro device array aligned with a backplane, according to one embodiment of the present invention.

FIG. 2D shows a cross-sectional view of the micro device array bonded to the backplane through bumps, according to one embodiment of the present invention.

FIG. 2E shows a cross-sectional view of the micro device array bonded to the backplane and a planarization layer, according to one embodiment of the present invention.

FIG. 3A shows a cross-sectional view of a micro device array, according to one embodiment of the present invention.

FIG. 3B shows a cross-sectional view of the micro device array with bumps, according to one embodiment of the present invention.

FIG. 4A shows a cross-sectional view of the micro device array, according to embodiments of the present invention.

FIG. 4B shows a top view of a micro device array, according to an embodiment of the present invention.

FIGS. 4C-4E show cross-sectional views of the micro device array, according to embodiments of the present invention.

FIG. 5A show cross-sectional view of the micro device array with bumps, a dielectric layer and a planarization layer, according to embodiments of the present invention.

FIG. 5B shows a cross-sectional view of the micro device array with bumps and etched dielectric and planarization layers, according to embodiments of the present invention.

FIG. 6A shows a bonding pad is formed on a substrate and an adhesive layer is patterned to form a nano pillar.

FIG. 6B shows adhesive in the pillar gets exposed as the conductive shell is damaged due to external stimulus.

FIG. 7A shows two types of pillars.

FIG. 7B shows the bonding process with two types of pillars.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

Unless defined otherwise, all technical and scientific terms used herein have the same meaning as commonly understood by one of ordinary skill in the art to which this invention belongs. As used in the specification and claims, the singular forms “a”, “an” and “the” include plural references unless the context clearly dictates otherwise. The term “comprising” as used herein will be understood to mean that the list following is non-exhaustive and may or may not include any other additional suitable items, for example one or more further feature(s), component(s) and/or element(s) as appropriate. The terms “device” and “micro device” are used herein interchangeably. However, it is clear to one skilled in the art that the embodiments described here are independent of the device size. The same applies to terms “pillar” and “nano pillar”. The term “bump” is also interchangeable with “pillar” or nano pillar”.

One of the challenges is to conduct selective transfer and bonding the micro device into the backplane. The present disclosure is related to a micro device array display device, wherein the micro device array may be bonded to a backplane with a reliable approach. In addition, the use of bumps or nano pillars to aid in the bonding process into the backplane is disclosed as well. The micro devices are fabricated over a micro device substrate. The micro device substrate may comprise micro light emitting diodes (LEDs), inorganic LEDs, organic LEDs, sensors, solid state devices, integrated circuits, microelectromechanical systems (MEMS), and/or other electronic components. The substrate may be the native substrate of the device layers or a receiver substrate where device layers or solid state devices are transferred to.

The receiver substrate may be any substrate and can be rigid or flexible. The system substrate may be made of glass, silicon, plastics, or any other commonly used material. The system substrate may also have active electronic components such as but not limited to transistors, resistors, capacitors, or any other electronic component commonly used in a system substrate. In some cases, the system substrate may be a substrate with electrical signal rows and columns. The system substrate may be a backplane with circuitry to derive microLED devices.

In one embodiment, an array of micro devices may be transferred or formed on a micro device substrate, wherein bumps are formed on a top surface of at least one micro device.

In another embodiment, a backplane may be provided. The backplane may be prepared the same way as the micro device substrate. The backplane may be provided with bumps/pads corresponding to the bumps on the micro devices.

In one embodiment, a space between the bumps in either the micro device array or the backplane is filled with adhesive layer(s) and patterned to remove the excess adhesive from the bumps. The adhesive material is removed from the surface of the bump. In another case, the material is removed from the side of the bumps. In this case the gap between the adhesive layer and bump can be covered by a dielectric layer.

In one embodiment, the micro device may be covered by a passivation layer and the space between the micro devices may be filled by a dielectric layer prior to the adhesive layer. The dielectric layer can be black matrix or reflective.

In another embodiment, the adhesive is photo-definable and the direct photolithography is used to remove the excess adhesive from the pads.

In some embodiments, the bumps may be conductive.

In another embodiment, a planarization layer may be formed on or over the array of micro devices covering the height of the micro devices. The planarization layer may be an adhesive layer.

In another embodiment, the adhesive layer is not conductive.

In some embodiments, the adhesive layer may be photo-definable.

In another embodiment, the adhesive layer may be patterned using either photolithography or a secondary layer to remove an excess adhesive from around the bumps, the micro devices or a top surface of the bumps. The secondary layer may be a photoresist layer.

In other embodiments, the backplane and array of micro devices may be aligned and connected through bumps. A pressure may be applied, and temperature, light, or microwave exposure may be used to cure and fuse the adhesive layers.

In one embodiment a pillar structure is used that has conductive layer(s) and adhesive layers on the pad of the backplane or the micro device. Application of pressure, temperature, light or other source of energy, exposes the adhesive layer and bonds the micro device into the backplane while the conductive layers couple the device into the backplane.

In yet another embodiment, the bumps may be formed over the micro devices after patterning with the planarization layer.

In one embodiment, the micro device array may have at least one common contact at lower layers of the micro device. In this case, a bridge/stage may be formed close to the same height of the micro device. The bridge may be passivated by one or more passivation/dielectric layers, where the dielectric or passivation layers cover a sidewall and surface of the micro devices and the bridge/stage.

In another embodiment, an electrode may be used to bring the common contact at the lower level to the top of the bridge prior to forming bumps. Pads are formed on the top of the electrode at the top of the bridge close to the height of bumps formed for the micro device.

In one embodiment, the bump of common contacts is a combination of more than one bump. In one case, the electrode for the common contact is covering more than one side of the array.

In one embodiment, the backplane has bumps corresponding to the common bump in the micro device array. The two bumps are bonded together through different means.

In another embodiment, the microdevice array may have a plurality of common layers.

In one embodiment, a dielectric layer may be deposited to cover at least isolated areas in between the microdevices with bonding pads.

In another embodiment, an exposed part of dielectric layer may be etched back so that a top surface of bonding pads is exposed/accessible.

In one embodiment, a planarization layer may be formed over the microdevice array and etch backed such that it is below the top surface of the bonding pads.

In another embodiment, the microdevice array may be bonded to another substrate (comprising different set of bonding pads and different microdevices or circuitry) through exposed surface of the bonding pads.

In the embodiments mentioned here, the adhesive layer can be cured either by light or temperature. The pressure will provide electrical contact between the pads of the backplane and microLEDs while adhesive layers provide mechanical stability. In addition, the space between the adhesion and the conductive pads provide room for expanding/deforming for accommodating surface profile non-uniformity. The various embodiments in accordance with the present structures and processes provided are described below in detail.

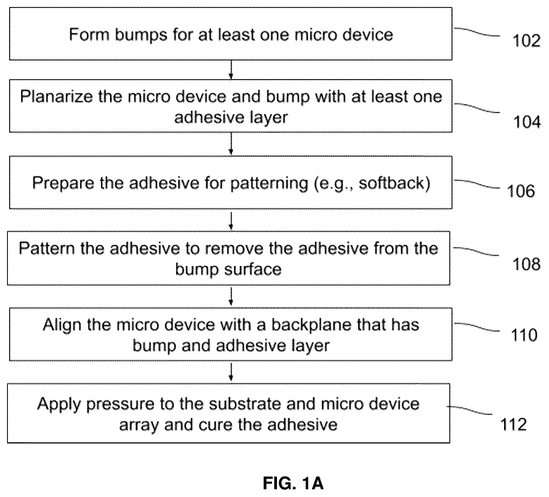

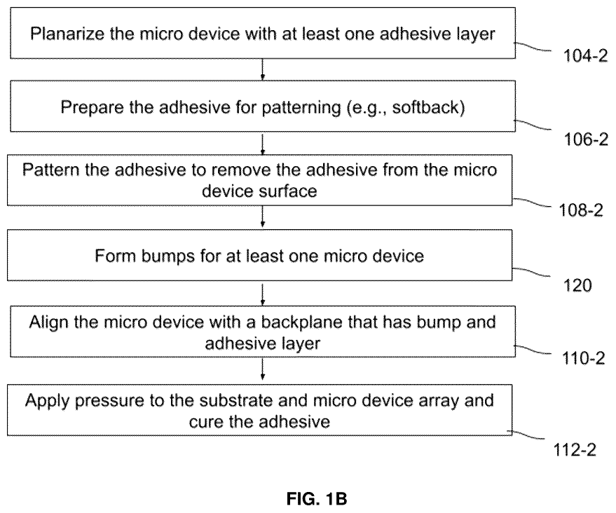

With reference to FIG. 1, a method to fabricate a micro device array is provided. The method comprises step 102, wherein at least one micro device is provided with a bump. During this step, at least one micro device may be formed or transferred on a micro device substrate. There may be a plurality of micro devices on the micro device substrate to form a micro device array. In one case, the bump provided on the at least one micro device is conductive. The micro device array may have one or more common layers. In one case, the common layer may be a second electrode. In another case, common layers may include active layers (e.g., quantum wells). The micro device may be covered by a passivation layer. The passivation layer may have an opening on top of the device to provide an electrical coupling path to the micro device. The passivation layer may include a reflector or opaque layer. The space between the micro devices can be at least partially filled by a planarization layer that can be also a black matrix or a reflector.

In one embodiment, the bump may be an ohmic contact layer or a thick conductive layer. To deposit the bump on the micro device, a conductive layer may be deposited over an upper surface of one of a plurality of device layers. The conductive layer may be a thick metallic layer or a non-metallic layer. The conductive layer deposition may be employed using a variety of methods such as thermal evaporation, e-beam deposition, sputtering, or coating. The conductive layer can also be a combination of different metals or conductive materials or layers. In one embodiment, the thick conductive layer provided over the ohmic contact layer may be used as a bump to bond the micro devices to a system substrate or a backplane. The thick conductive layer of materials such as Ni/Au, Cr/Au or Ti/Au may be formed over the ohmic contact layer.

During the next step 104 of FIG. 1, at least one planarization layer may be deposited on or around the micro devices and each bump for planarization. The micro devices may have one or more passivation layers formed around them. In one case, a planarization layer may be formed on or over the array of micro devices and cover a height of micro devices. The planarization layer may be an adhesive layer. There may be a second adhesive planarization layer that may cover the rest around an edge of the bump. The adhesive layer may comprise polyamide, SU8, PMMA, BCB thin film layers, epoxies, and UV curable adhesives. Adhesive material may be selected so that it will cure when pressure is applied. The adhesive layer can be applied in many ways. For example, adhesive can be applied to any or all of the micro devices. However, the adhesive layer is not conductive. The adhesive layer may be photo definable and photolithography may be used to pattern it. During the next step 106, the adhesive layer may be prepared for patterning (e.g., softback). Depending on the patterning step, the adhesive layer may undergo some processing steps. In the case of direct photolithography, the adhesive layer is typically softbacked and exposed to a light with mask pattern. In the case of indirect patterning, another mask material is formed on top of the adhesive layer and the mask is patterned by photolithography means and wet or dry etch. In another case, the mask is used to create a pattern in the adhesive through wet or dry etching.

During the next step 108, the adhesive may be patterned to remove an excessive adhesive from the top surface of the bump. Also, the adhesive may be removed from around the bump to create space for the adhesive and the bump to move during the bonding process. Since the adhesive layer is not conductive, the top surface of the bump is exposed to make a contact to bond the micro devices to a backplane. Since the adhesive layer can be photo definable and direct photolithography can be used to pattern it. Also, a secondary layer may be used to pattern it to remove the excess adhesive. The secondary layer may be a photoresist layer.

In another case, the adhesive layer comprises a functional surface (e.g., oxide) and materials that can form the bonding with the functional surface.

In one embodiment, the backplane may be prepared the same way as the micro device substrate. The backplane may be prepared with conductive bumps fabricated on it. Next, a secondary adhesive layer may be deposited on the bumps on the backplane for planarization and may be patterned to remove the adhesive from the top of the bump surface and expose the metal contact for connection.

During the next step 110, the micro device substrate having micro devices with bumps and an adhesive layer and the backplane with bumps and the secondary adhesive layer may be aligned.

During the next step 112, after aligning, the backplane may be brought in contact with the micro devices so that the bumps on both sides interconnect. At this stage, pressure can be applied, and temperature, light, or microwave exposure can be used to cure and fuse the adhesive layers.

It should also be noted that activities performed during steps 102-112 may sometimes be interspersed with one another. In an alternative embodiment, there may be another approach to form a microdisplay.

With reference to FIG. 1B, another method to manufacture a microdisplay or a micro device array is provided. The method comprises: step 104-2, wherein at least one planarization layer is formed around an array of micro devices. The array of micro devices may be transferred or formed on a micro device substrate. The planarization layer may be deposited on sidewalls or (on or over) the micro devices for planarization. The micro device may have one or more passivation layers formed around them. In one case, the micro device may comprise one planarization layer to cover around a height of the micro device. The planarization layer may be an adhesive layer. The adhesive layer may comprise polyamide, SU8, PMMA, BCB thin film layers, epoxies, and UV curable adhesives. The adhesive layer can be photo definable and photolithography may be used to pattern it.

During the next step 106-2, the adhesive layer may be prepared for patterning (e.g., softback). Depending on the patterning step, the adhesive layer may undergo some processing steps. In the case of direct photolithography, the adhesive layer is typically softbacked and exposed to a light with a mask pattern. In the case of indirect patterning, another mask material is formed on top of the adhesive layer the mask is patterned by means of photolithography and wet or dry etch. And the mask is used to create a pattern in the adhesive through wet or dry etching.

During the next step 108-2, the adhesive may be patterned to remove the excessive adhesive from the top of the micro device surface. In one embodiment, the patterning creates a via in the adhesive layer. As the adhesive layer is not conductive, a contact layer may need to be deposited over the micro devices.

During the next step 120, a bump may be provided over at least one micro device. The bump can be formed inside the via/opening of the adhesive layer. In one embodiment, the bump may be an ohmic contact layer or a thick conductive layer. In order to deposit the bump on the micro device, a conductive layer may be deposited over an upper surface of one of a plurality of device layers. The conductive layer deposition may be employed using a variety of methods such as thermal evaporation, e-beam deposition, and sputtering. The conductive layer may also be a combination of different metals or conductive materials or layers. In one embodiment, the thick metal layer provided over the ohmic contact layer may be used as a bump to bond the micro devices to a system substrate or a backplane. The thick metal layer of materials such as Ni/Au, Cr/Au or Ti/Au may be formed over the ohmic contact layer.

In one embodiment, the backplane may be prepared the same way as the micro device substrate. The backplane may be prepared with conductive bumps fabricated on it. Next, a secondary adhesive layer may be deposited on the bumps on the backplane for planarization and may be patterned to remove the adhesive from the top of the bump surface and expose the metal contact for connection.

During the next step 110-2, the micro device substrate having micro devices with bumps and an adhesive layer, and the backplane with bumps and the secondary adhesive layer, may be aligned.

During the next step 112-2, after aligning, the backplane may be brought in contact with the micro devices so that the bumps on both sides connect. At this stage, pressure can be applied and temperature, light, or microwave exposure can be used to cure and fuse the adhesive layers.

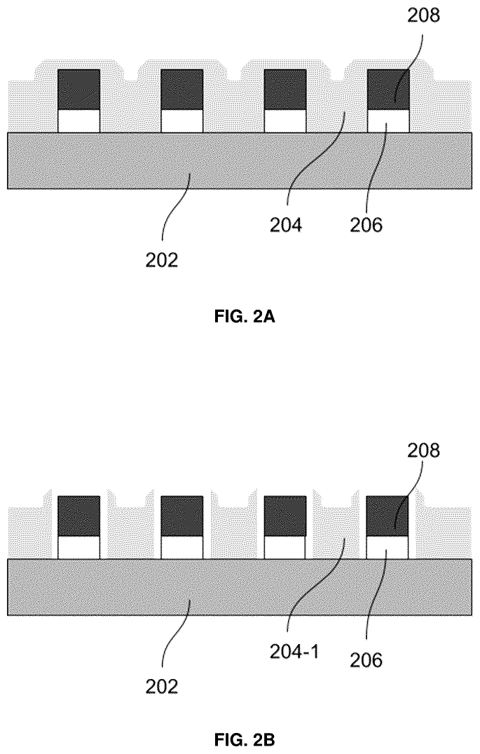

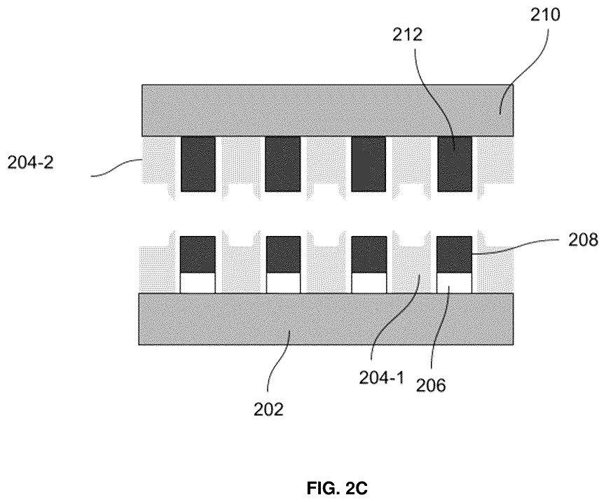

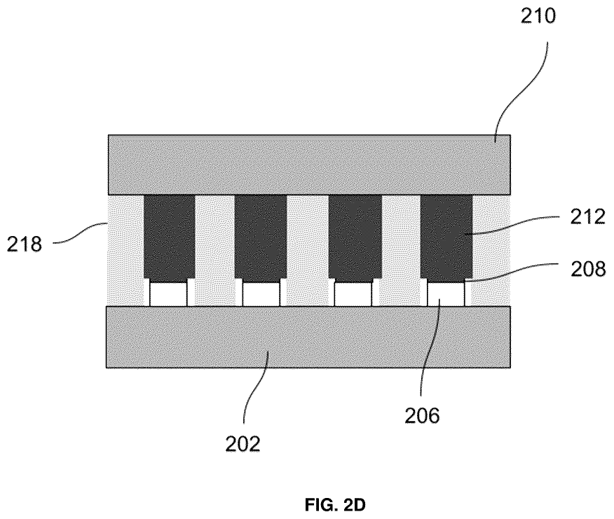

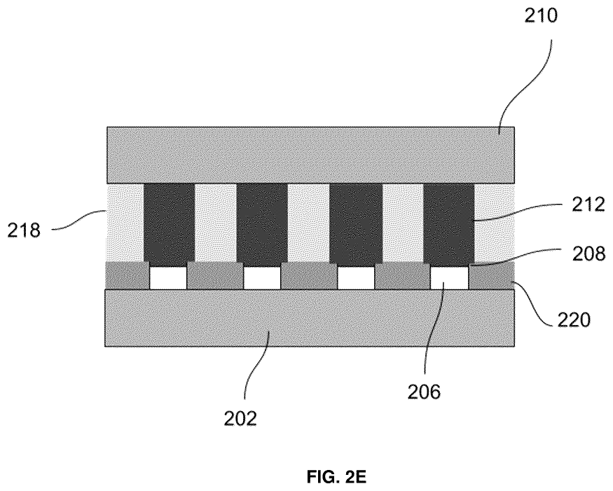

FIG. 2A-2E may be described with reference to FIG. 1A that describes a method to manufacture a microdisplay.

With reference to FIG. 2A, a micro device substrate 202 may be provided. An array of micro devices 206 may be formed or transferred to the micro device substrate 202. Micro devices 206 can be any micro device that may typically be manufactured in planar batches including but not limited to LEDs, inorganic LEDs, OLEDs, sensors, solid state devices, integrated circuits, MEMS, and/or other electronic components. The micro device array may have common layers. In one case, the common layer can be a second electrode. In another case, common layers may include active layers (e.g,. quantum wells). The micro device may be covered by a passivation layer. The passivation layer may have an opening on top of the device to provide an electrical coupling path to the micro device. The passivation layer may include a reflector or opaque layer. The space between the micro devices may be at least partially filled by a planarization layer that can be also a black matrix or a reflector.

In one embodiment, bumps 208 may be provided on at least one micro device. The bumps are conductive. The bump may be an ohmic contact layer or a thick conductive layer. To deposit the bump on the micro device, a conductive layer may be deposited over an upper surface of one of a plurality of device layers. The conductive layer may be a thick metal layer or non-metallic layer. The conductive layer deposition may be employed using a variety of methods such as thermal evaporation, e-beam deposition, sputtering, or coating. The conductive layer may also be a combination of different metals or conductive materials or layers. In one embodiment, the thick conductive layer provided over the ohmic contact layer may be used as a bump to bond the micro devices to a system substrate or a backplane. The thick conductive layer of materials such as Ni/Au, Cr/Au or Ti/Au may be formed over the ohmic contact layer.

Furthermore, at least one planarization layer 204 may be deposited on or around the micro devices 206 and the bump 208 for planarization. The micro devices may have one or more passivation layers formed around them. In one case, the micro device may comprise one planarization layer to cover around a height of the micro device. The planarization layer 204 may be an adhesive layer. There may be a second adhesive planarization layer that may cover the rest around an edge of the bump. The adhesive layer may comprise polyamide, SU8, PMMA, BCB thin film layers, epoxies, and UV curable adhesives. The adhesive layer may be photo definable and photolithography may be used to pattern it.

With reference to FIG. 2B, the adhesive layer may be prepared for patterning (e.g., softback). Depending on the patterning step, the adhesive layer may undergo some processing steps. In the case of direct photolithography, the adhesive layer is typically softbacked and exposed to a light with a mask pattern. In the case of indirect patterning, another mask material is formed on top of the adhesive layer and the mask is patterned with photolithography and wet or dry etch. In another case, the mask is used to create a pattern in the adhesive through wet or dry etching.

The adhesive may be patterned to remove the excessive adhesive from a top of the bump surface. Also, the adhesive may be removed from around the bump to create space for the adhesive and the bump to move during the bonding process. Since the adhesive layer is not conductive, the top surface of the bump is exposed to make a contact to bond the micro devices to a backplane. In another case, the adhesive layer comprises a functional surface (e.g., oxide and materials that can form bonding with the functional surface).

With reference to FIG. 2C, the backplane 210 may be prepared the same way as the micro device substrate. The backplane may be prepared with conductive bumps 212 fabricated on it. Next, a secondary adhesive layer 204-2 may be deposited on the bumps 212 on the backplane 210 for planarization and may be patterned to remove the adhesive from the top of the bump surface and expose the metal contact for connection. In the next step, the micro device substrate 202 with micro devices 206 with bumps 208 and adhesive layer 204-1, and the backplane 210 with bumps 212 and the secondary adhesive layer 204-2, may be aligned.

With reference to FIG. 2D, after aligning, the backplane 210 may be brought in contact with the micro devices 206 for connection through the bumps (212, 208). At this stage, pressure can be applied, and temperature, light, or microwave exposure can be used to cure and fuse the adhesive layers 218.

With reference to FIG. 2E, another planarization layer 220 may be deposited on spaces between the micro devices 206. The space between the micro devices may be filled with a dielectric layer prior to an adhesive layer. The dielectric layer can be black matrix or reflective.

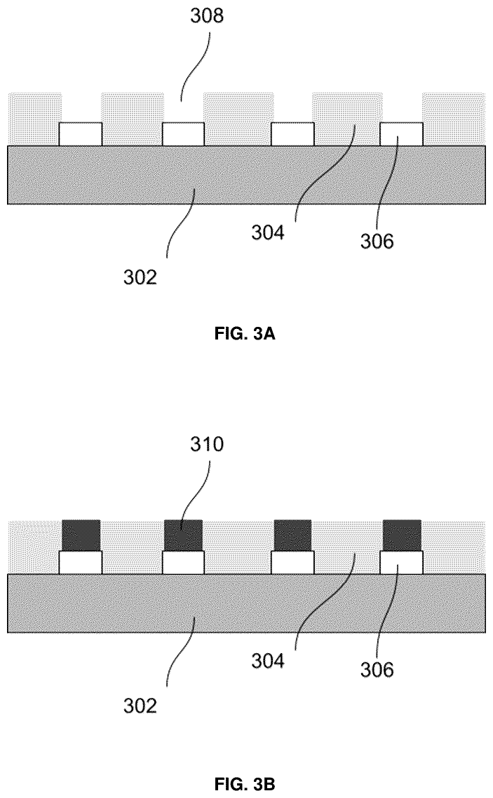

FIG. 3A-3B may be described with reference to FIG. 1B that describes another method of manufacturing a microdisplay. With reference to FIG. 3A, an array of micro devices 306 may be formed or transferred on a micro device substrate 302. A planarization layer 304 may be deposited on the micro devices 302 for planarization. The micro device 306 may have one or more passivation layers formed around them. In one case, the micro device may comprise one planarization layer to cover around a height of the micro device. The planarization layer 304 may be an adhesive layer. The adhesive layer may comprise polyamide, SU8, PMMA, BCB thin film layers, epoxies, and UV curable adhesives. The adhesive layer may be prepared for patterning (e.g., softback). Depending on the patterning step, the adhesive layer may undergo some processing steps. In the case of direct photolithography, the adhesive layer is typically softbacked and exposed to a light with a mask pattern. In the case of indirect patterning, another mask material is formed on top of the adhesive layer and the mask is patterned using photolithography and wet or dry etch. As well, the mask is used to create a pattern in the adhesive through wet or dry etching. The adhesive layer can be photo definable and photolithography may be used to pattern it.

In one embodiment, the adhesive may be patterned to remove the excessive adhesive from the top of the micro device surface to create openings 308.

With reference to FIG. 3B, a bump 310 may be provided over the at least one micro device 306 in the opening 308 of the adhesive layer. In one embodiment, the bump 310 may be an ohmic contact layer or a thick conductive layer. In order to deposit the bump on the micro device 306, a conductive layer may be deposited over an upper surface of one of a plurality of device layers. The conductive layer deposition may be employed using a variety of methods such as thermal evaporation, e-beam deposition, and sputtering. The conductive layer may also be a combination of different metals or conductive materials or layers. In one embodiment, the thick metal layer provided over the ohmic contact layer may be used as a bump to bond the micro devices to a system substrate or a backplane. The thick metal layer of materials such as Ni/Au, Cr/Au or Ti/Au may be formed over the ohmic contact layer.

In one embodiment, the backplane may be prepared the same way as the micro device substrate. The backplane may be prepared with metal bumps fabricated on it. Next, a secondary adhesive layer may be deposited on the bumps on the backplane for planarization and may be patterned to remove the adhesive from the top of the bump surface and expose the metal contact for connection.

Furthermore, the micro device substrate having micro devices with bumps and adhesive layer, and the backplane with bumps and the secondary adhesive layer, may be aligned.

After aligning, the backplane may be brought into contact with the micro devices so that the bumps on both sides connect. At this stage, pressure can be applied, and temperature, light, or microwave exposure can be used to cure and fuse the adhesive layers. Another planarization layer may be deposited on spaces between the micro devices.

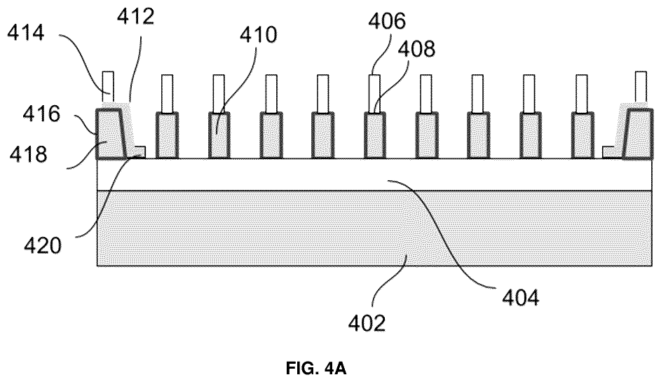

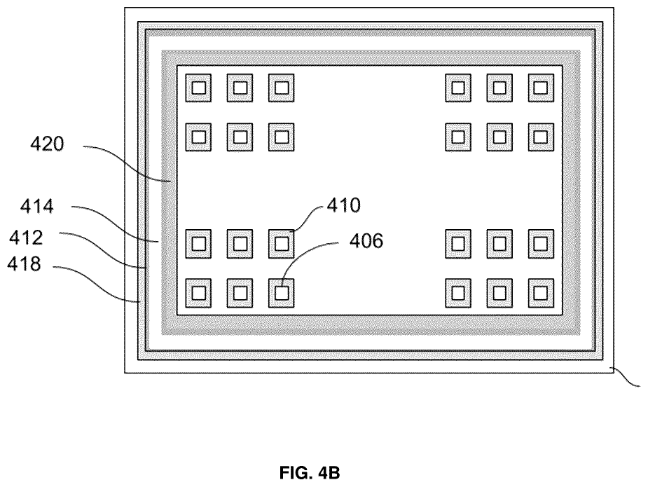

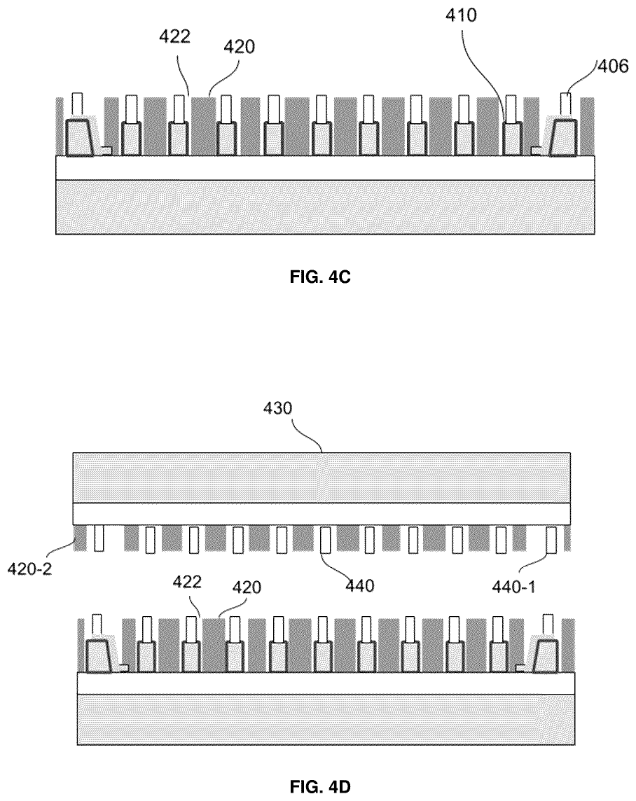

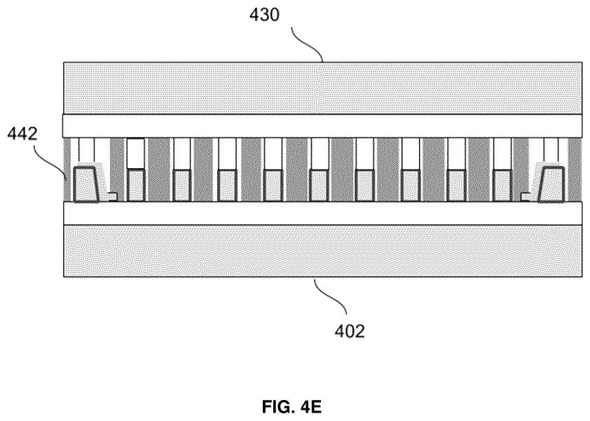

FIG. 4A-4E shows views of the micro device array, according to embodiments of the present invention.

In one embodiment, the micro device array may have at least one common contact at lower layers of the micro device. In this case, a bridge/stage is formed close to the same height of the micro devices. The bridge is passivated by a dielectric layer. An electrode is used to bring the common contact at the lower level to the top of the bridge/stage prior to forming bumps on the micro devices. A common pad/bump of the common contact is formed on the top of the electrode at the top of the bridge/stage close to the height of the bumps formed for the micro devices. In one embodiment, the pad of the common contact is a combination of more than one pad. In one case, the electrode for the common contact covers more than one side of the array.

In one embodiment, the backplane has bumps corresponding to the common bump in the micro device array. The two bumps are bonded together through different means.

With reference to FIG. 4A, a substrate 402 may be provided. A plurality of common layers 404 may be deposited on the substrate. The common layers 404 may comprise extra device layers, buffer layers, and/or active layers. An array of micro devices 410 may be fabricated on a top layer of the common layers. In one case, the common layers may be etched further down to form a common contact 420 on the common layers. The common contact 420 may be deposited after etching down the common layers. The common contact 420 may be deposited as a ring around the micro device array or may be segmented. In one case, a bridge/stage 418 is formed close to the same height of the micro devices 410. The bridge may be passivated by one or more passivation/dielectric layers 416. The dielectric or passivation layers 416 cover the sidewall and surface of the micro devices and the bridge/stage 418.

An electrode 412 may be deposited to bring the common contact 420 to a top surface of a bridge/stage 418 to provide a connection to a pad 414. The pad 414 may be a ring around the micro device formed during the etching process. In one case, the pad 414 may be a combination of a few isolated pads. The bridge/stage 418 and micro devices may be formed during the etching process. In one embodiment, one or more passivation or dielectric layers 416 may be formed to cover the sidewalls and surface of the micro devices and the stage layer.

In another case, a bridge/stage 418 is formed outside the micro device array. The stage can be a similar structure as micro device 410. The stage or micro devices are covered by a dielectric layer 416. A contact 420 can be formed to a common layer 440. The contact 420 is then brought to the top of the stage 418 by an electrode 412. A pad/bump 414 is formed on top of the electrode 412. The electrode 412 can be covered by another dielectric layer. A part of at least one passivation/dielectric layer 416 is open to provide a connection path for a first contact 408, first pad 406, and the micro device. The first pad 406 may exist on top of the first contact 408 and the device layers. The stage can be a continuous ring around the array or a collection of several smaller stages.

FIG. 4B shows a top view of FIG. 4A, wherein an array of micro devices 410 with bumps 406 are formed on a substrate. There can be common layers formed on the micro device substrate. In one case, the common layers may be etched further down to form a common contact 420 on the device layers. The common contact 420 may be deposited after etching down the device layers. The common contact 420 may be deposited as a ring around the micro device array or may be segmented. In one case, a bridge/stage 418 is formed close to the same height of the micro devices 410. An electrode 412 may be deposited to bring the common contact 420 to a top surface of a bridge/stage 418 to provide a connection to a common pad 414. The common pad 414 may be a ring around the micro device formed during the etching process. In one case, the common pad 414 may be a combination of a few isolated pads. The bridge/stage layer 418 and micro devices may be formed during the etching process.

FIG. 4C shows the micro device array of FIG. 4A and the patterning of an adhesive layer. There may be one or more planarization layers formed around the micro devices. In one case, a first planarization layer may be deposited to cover a part or all of the micro devices 410. There may be a second planarization layer formed for a final top layer. The second planarization layer may be an adhesive layer 420. Each planarization layer may have multiple layers. The second planarization/adhesive layer may be patterned to provide opening 422 on top of the pads 406. The first planarization layer does not need to be patterned.

With reference to 4D, a backplane 430 may be prepared the same way as the micro device substrate. The backplane may be prepared with bumps/contact pads 440 fabricated on it. The backplane may also have bumps 440-1 corresponding to the common bumps in the micro device array. Next, a secondary adhesive layer 420-2 may be deposited on the contact pads 440 on the backplane 430 for planarization and may be patterned to remove the adhesive from the top of the contact pads to open the top of the contact pads. Furthermore, the micro device substrate and the backplane may be aligned.

With reference to FIG. 4E, after aligning, the backplane 430 may be brought into contact with the micro devices so that the bumps on both sides connect. At this stage, pressure can be applied, and temperature, light, or microwave exposure can be used to cure and fuse the adhesive layers 442. Curing may create a permanent bond between micro devices and the backplane. Another planarization layer may be deposited on spaces between the micro devices.

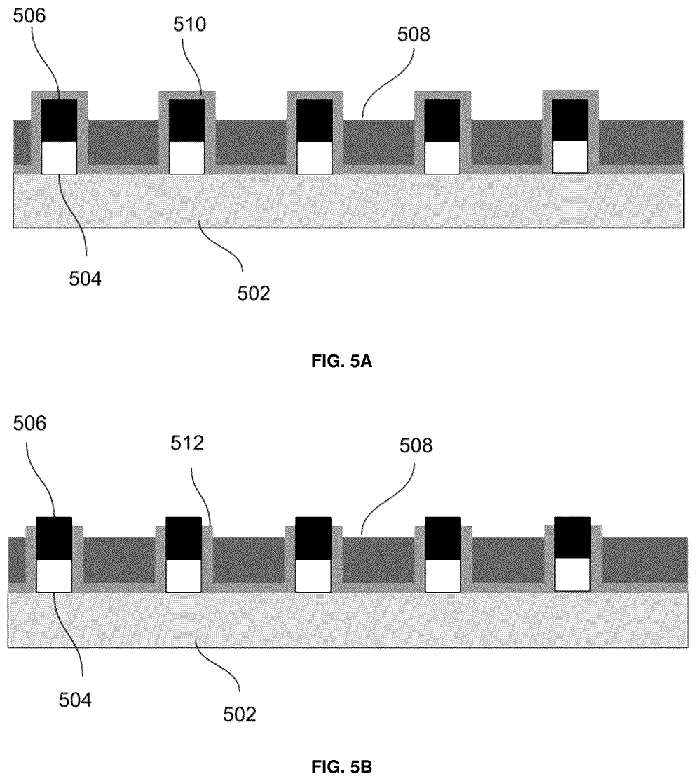

With reference to FIG. 5A, a micro device substrate 502 may be provided. An array of micro devices 504 may be formed or transferred to the micro device substrate 502. Micro devices 504 can be any micro device that may typically be manufactured in planar batches including but not limited to LEDs, inorganic LEDs, OLEDs, sensors, solid state devices, integrated circuits, MEMS, and/or other electronic components. The micro device array may have common layers. In one case, the common layer can be a second electrode. In another case, common layers may include active layers (e.g., quantum wells).

In one embodiment, bonding pads/bumps 506 may be formed on top of microdevices. In one case, the bonding pads may be used to etch some or all of microdevice layers to isolate the microdevices fully or partially.

The bonding pads may be conductive. In one aspect, the bonding pad may be an ohmic contact layer or a thick conductive layer. To deposit the bonding pad on the micro device, a conductive layer may be deposited over an upper surface of one of a plurality of device layers. The conductive layer may be a thick metal layer or non-metallic layer. The conductive layer deposition may be employed using a variety of methods such as thermal evaporation, e-beam deposition, sputtering, or coating. The conductive layer may also be a combination of different metals or conductive materials or layers.

In another embodiment, a dielectric layer 510 may be deposited to cover at least between the isolated parts of microdevices. The dielectric layer can cover the sidewall of the isolated part of microdevices (and bonding pads) and/or a top surface of the pads. The dielectric layer can be deposited by atomic layer deposition (ALD), plasma-enhanced chemical vapor deposition (PECVD), and other forms of deposition.

In one embodiment, at least one planarization layer 508 may be deposited on or around the micro devices 504 and the bonding pads 506 for planarization. The micro devices may have one or more passivation layers formed around them. In one case, the micro device may comprise one planarization layer to cover around a height of the micro device. In another case, the planarization layer may be etched back so that it is below a top surface of the bonding pads.

With reference to FIG. 5B, the exposed part of dielectric layer 512 is etched so that the top surface of the bonding pads 506 is accessible/exposed. This structure can be bonded to another substrate (that may include a different set of bonding pads and different microdevices or circuitry) through exposed surface of the bonding pads.

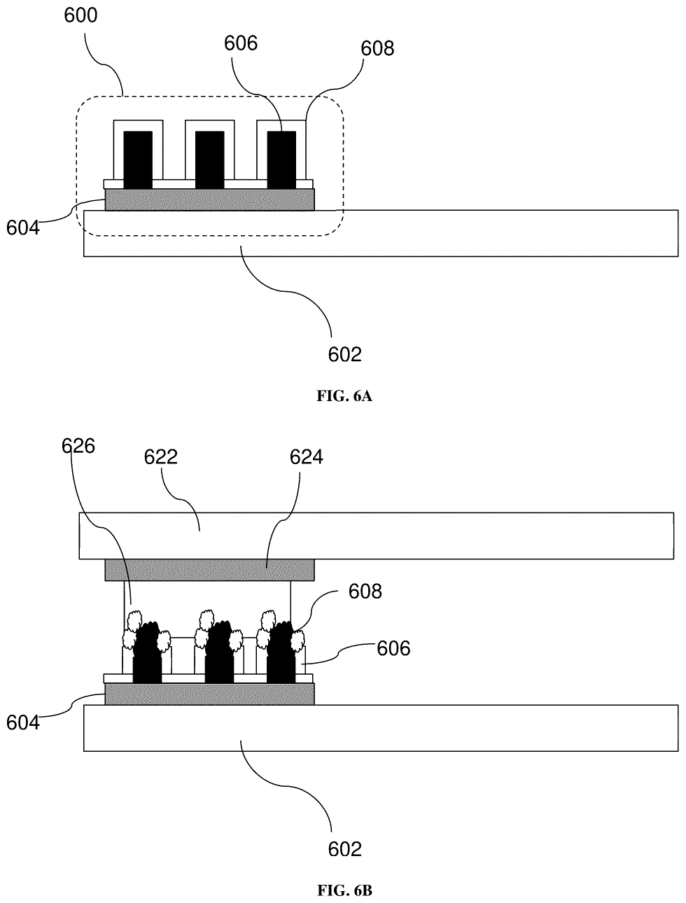

As demonstrated in FIG. 6A, a bonding pad 600 is formed on a substrate 602. The substrate could be a receiver/backplane or a donor substrate with micro devices. The bonding pad 600 can be on a micro device or it can provide access to the backplane. The bonding pad 600 can have a base conductive layer 604. This base conductive layer is coupled either to the micro device or the backplane. At least one adhesive layer 106 is patterned to form one nano pillar. The size and height of the pillar(s) can be adjusted based on the device size and bonding parameters. One or more conductive layer(s) 608 is formed to at least cover part of the adhesive pillar 606. The conductive layer 608 can be coupled to the base conductive layer 604. Another conductive layer can be buried within the adhesive pillar 606.

FIG. 6B shows the bonding process. Here, another substrate 622 with a conductive layer 624 and bonding pad 626 is brought close to the bonding pad 600. The bonding pad 626 can have a similar adhesive-conductive core-shell structure. The adhesive 608 in the pillar gets exposed as the conductive shell 106 is damaged due to external stimulus (e.g. pressure, light, electrical, etc.). The exposed adhesive can form bonding to the pad 626. The bonding can be accelerated, initiated, or performed by external sources such as temperature, light, or electrical. In the case of using light as a curing source, the conductive shell 606 can be opaque for that light source so that only the exposed adhesive gets affected. In this case, the pillars that are not part of the transfer cycle will not have exposed epoxy and so the light will not degrade the integrity of the adhesive material. And as such it can be used in a next transfer/bonding cycle.

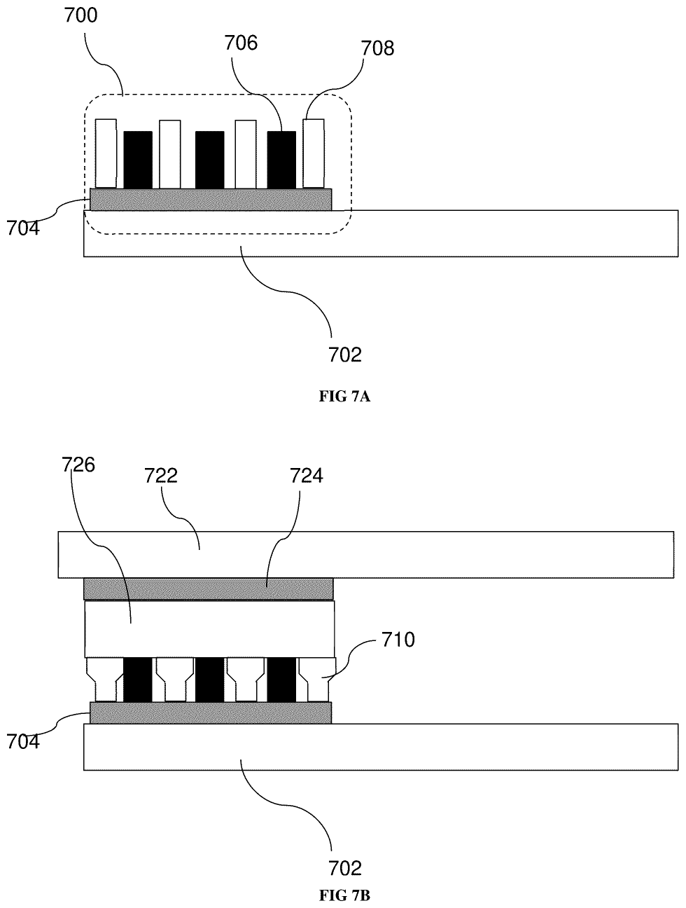

FIG. 7A shows another embodiment, where there are at least two types of pillars in one bonding pad 700. One type of pillar is made of an adhesive 708 or bonding materials and the other type of pillar is made of conductive material 706. The adhesive pillar 708 can be patterned out of the adhesive or bonding material. The pillar made of conductive material can be patterned out of a conductive material. These pillars can be on top of a conductive electrode 704 on a substrate 702. The substrate can be a receiver substrate with other components, layers and devices, or it can be a donor substrate with micro devices.

The shape of the adhesive pillar 208 can be different (e.g. cylindrical, ring, etc.). The adhesive pillar can be distributed between, around or inside the conductive pillar 706.

FIG. 7B shows the bonding process. Here, the adhesive pillar 710 is a deformed due to external stimulus (e.g. pressure, light, electrical, etc.). The deformed adhesive pillar 710 can form a bonding to the pad (or device) 726. The pad (or device) 726 can be on another structure 724. The structure 724 can be conductive, release layer, or bonding layer. The bonding can be accelerated, initiated, or performed by external sources such as temperature, light, or electrical.

In one case, adhesive pillars can be taller than conductive pillars. Here, during the bonding process, the other pads or device from the other substrate 722 (e.g. microdevice, or receiver substrate) first get attached to the adhesive pillars. Either during the transfer or after transfer, further pressure can connect the pads or devices from other substrate to the conductive pillar. The conductive pillar can deform for further connections. The adhesive pillars can be cured during or after the transfer. The transfer is the process of moving microdevices from one substrate (donor substrate) to another substrate (receiver substrate). Here the adhesive pillars or layers hold the device in place. Here either the bonding pads exist on the micro device or on the receiver substrate.

In another case, the adhesive pillar can be shorter or the same as the conductive pillars. The bonding pressure deforms the conductive pillars and connects the pads or devices from other the substrate to the adhesive pillar. Curing during or after transfer holds the device in place and connects to the conductive pillar.

According to one embodiment, a method to fabricate a micro device array may be provided. The method comprises providing a substrate having one or more micro devices with a bump at a top surface of the micro devices, providing a backplane comprising one or more bumps corresponding to the bumps on the micro devices, planarizing spaces between the micro devices and the bumps with at least one planarization layer, patterning the at least one planarization layer to clear the bumps, aligning and bringing the microdevices and the backplane in contact; and curing the at least one planarization layer.

According to yet other embodiment, the method further comprises applying pressure before curing the at least one planarization layer, wherein the at least one planarization layer is an adhesive layer, and providing a passivation layer on or over the micro device prior to the adhesive layer, wherein the passivation layer is a dielectric layer, a black matrix, or a reflective layer.

According to some embodiments, patterning the at least one planarization layer comprises removing an excess adhesive from around the bump or micro device or the top surface of the bumps, patterning the at least one planarization layer comprises patterning the at least one planarization layer through direct photolithography or applying a photoresist layer, wherein a surface of the patterned planarized layer is functionalized to bond to some adhesive materials.

According to further embodiments, curing the at least one planarization layer comprises curing through one of a thermal process or an optical process and planarizing spaces between the micro devices comprises providing a passivation layer that covers around a height of the at least one microdevice and a dielectric layer to covers the spaces between the micro devices, wherein planarizing spaces between the bumps providing an adhesive layer that covers around an edge of the bump. The adhesive layer is not conductive, and the bump is conductive

According to another embodiment, a microdisplay may be provided. A microdisplay comprising a substrate having one or more micro devices with bumps on a top surface of the one or more micro devices, a backplane comprising one or more bumps corresponding to the bumps on the one or more micro devices, and at least one patterned planarization layer that covers spaces between the micro devices and the bumps, wherein the substrate and the backplane are aligned and connected through curing the at least one patterned planarization layer.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

What is claimed is:

1. A method to fabricate a microdevice array comprising:
providing a microdevice substrate having one or more micro devices with bonding pads at a top surface of the microdevices; and
providing at least one dielectric layer around the microdevices.

2. The method of claim 1, wherein providing at least one dielectric layer around the microdevices comprises providing the dielectric layer to cover sidewalls of isolated parts of microdevices and the bonding pads.

3. The method of claim 1, wherein providing at least one dielectric layer around the microdevices comprises providing the dielectric layer to cover a top surface of the bonding pads.

4. The method of claim 1, further comprising:
etching the dielectric layer to expose the top surface of the bonding pads.

5. The method of claim 2, further comprising:
planarizing spaces between the microdevices and the bonding pads with at least one planarization layer; and
patterning the at least one planarization layer to clear the top surface of the bonding pads.

6. The method of claim 2, further comprising:
providing another substrate comprising one or more bonding pads corresponding to the bonding pads on the micro devices; and
bonding the other substrate to the microdevice substrate through exposed top surface of the bonding pads on the micro devices.
